(19) United States
(12) Patent Application Publication
(10) Pub. No.: US 2026/0269836 A1
(43) Pub. Date: Sep. 10, 2026

(54) Calibration Method, Apparatus, and Circuit for Channel Gain Mismatch of Analog-to-Digital Converter (ADC)

(71) Applicant: Sanechips Technology Co., Ltd., Shenzhen (CN)

(72) Inventor: Xiao CHEN, Shenzhen (CN)

(21) Appl. No.: 19/130,791

(22) PCT Filed: Jun. 30, 2023
(86) PCT No.: PCT/CN2023/104540

§ 371 Date: May 16, 2025

(30) Foreign Application Priority Data
Dec. 30, 2022 (CN) 202211736878.2

(51) Int. Cl. H03M 1/10

(52) U.S. Cl. CPC H03M 1/1014

(57) ABSTRACT

Provided in the embodiments of the present application are a calibration method and apparatus for a channel gain mismatch of an ADC, and a circuit. The method comprises: inputting, into a non-reference channel of an ADC, an analog input value determined on the basis of a reference channel, so as to obtain a first digital output code value corresponding to the non-reference channel; respectively comparing the first digital output code value with a first threshold value and a second threshold value, and according to comparison results, adjusting an initial value of a channel gain calibration code corresponding to the non-reference channel; and assigning the adjusted channel gain calibration code to the non-reference channel, so as to complete the operation of channel gain calibration.

### CROSS REFERENCE

This disclosure is a national stage filing under 35 U.S.C. § 371 of international application number PCT/CN2023/104540, filed Jun. 30, 2023, which claims the benefit of priority of Chinese patent application No. CN202211736878.2, filed on Dec. 30, 2022, the entire contents of which are incorporated herein by reference.

### TECHNICAL FIELD

Embodiments of the present disclosure relate to the technical field of high-speed electronic communications, and in particular, to a calibration method, apparatus, and circuit for channel gain mismatch of an Analog-to-Digital Converter (ADC).

### BACKGROUND

With the development of Fifth Generation (5G) communication technologies and integrated circuit manufacturing processes, a working speed of Analog-to-Digital Converter (ADC) circuits is becoming faster and faster. Generally, the working speed of a single-channel ADC cannot meet design requirements, so a multi-channel ADC structure is generally used in conjunction with time-interleaving technology to realize an ultra-high-speed ADC. However, due to the limitations of integrated circuit manufacturing processes, performance parameters of sub-ADCs of different channels (sometimes also referred to as ADCs of different sub-channels, or sub-channel ADCs, or channel ADCs hereinafter) are not completely consistent. Taking a channel gain as an example, if there is a mismatch in the channel gains of the sub-ADCs on various channels, an output signal spectrum of the entire time-interleaved ADC will have higher harmonics at specific frequency points, which will affect the performance of the entire time-interleaved ADC. Therefore, it is necessary to calibrate the channel gain of each sub-channel ADC. In addition, since multi-channel ADC arrays converts the same type of signal synchronously, the corresponding parameters for respective sub-channel ADCs should also be as consistent as possible, so the gain mismatch between different sub-channel ADCs in the ADC array also needs to be calibrated.

The calibration method for the multi-channel gain in related art involves converting gain mismatch information of respective sub-channel ADCs obtained in a digital domain into an analog domain, and then calibrating a channel gains of each sub-channel ADC by adjusting a reference value of an analog reference voltage for each channel. However, since the adjustment function is implemented in the analog domain, the precision of this calibration circuit highly depends on the precision of the analog circuit. Therefore, there are high requirements for the precision of the analog circuit design. If the precision of the analog circuit is not good enough, the final calibration precision will decrease.

### SUMMARY

The embodiments of the present disclosure provide a calibration method, apparatus, and circuit for channel gain mismatch of an ADC, which may at least solve a problem in the related art that a calibration method for multi-channel gain that relies on an analog circuit has relatively low calibration precision.

According to an embodiment of the present disclosure, provided is a calibration method for channel gain mismatch of an ADC. The calibration method includes: inputting, into a non-reference channel of the ADC, an analog input value determined based on a reference channel so as to obtain a first digital output code value corresponding to the non-reference channel; comparing the first digital output code value with a first threshold and a second threshold respectively, and adjusting a channel gain calibration code corresponding to the non-reference channel based on a comparison result; and assigning the adjusted channel gain calibration code to the non-reference channel to complete channel gain calibration.

According to another embodiment of the present disclosure, provided is a calibration apparatus for channel gain mismatch of an ADC. The calibration apparatus includes: an inputting module, configured to input, into a non-reference channel of the ADC, an analog input value determined based on a reference channel so as to obtain a first digital output code value corresponding to the non-reference channel; an adjustment module, configured to compare the first digital output code value with a first threshold and a second threshold respectively, and adjust a channel gain calibration code corresponding to the non-reference channel based on a comparison result; and an assignment module, configured to assign the adjusted channel gain calibration code to the non-reference channel to complete channel gain calibration.

According to still another embodiment of the present disclosure, provided is a calibration circuit for channel gain mismatch of an ADC. The calibration circuit includes: a reference voltage generating circuit, a reference voltage driving circuit, ADCs, and a channel gain calibration module, wherein the reference voltage generating circuit is configured to provide a reference voltage according to a parameter requirement of the calibration circuit for the channel gain mismatch of the ADC, and send the reference voltage to the reference voltage driving circuit; the reference voltage driving circuit is configured to provide a reference voltage for an ADC unit of each channel in M channels, wherein the M channels include one reference channel and M-1 non-reference channels, and M is an integer greater than 1; the ADC includes N-bit ADC units corresponding to the M channels, and each of the N-but ADC units is configured to convert an input differential analog voltage signal of the reference voltage into a digital output signal and output the digital output signal, wherein N is an integer greater than zero; and the channel gain calibration module is configured to calculate and adjust a gain coefficient for a digital output code value output by the ADC unit of each channel, and determine a gain calibration code corresponding to each channel.

According to yet another embodiment of the present disclosure, provided is a computer readable storage medium. The computer readable storage medium stores a computer program, and the computer program, when running, is used for implementing operations in any one of the method embodiments.

According to yet another embodiment of the present disclosure, provided is an electronic device, including: a memory, a processor, and a computer program stored in the memory and capable of running on the processor, wherein the processor, when executing the computer program, implements operations in any one of the method embodiments.

### BRIEF DESCRIPTION OF THE DRAWINGS

FIG. 1 is a hardware structure block diagram of a computer terminal for implementing a calibration method for channel gain mismatch of an ADC according to some embodiments of the present disclosure;

FIG. 2 is a flowchart of a calibration method for channel gain mismatch of an ADC according to some embodiments of the present disclosure;

FIG. 3 is a structural block diagram of a calibration apparatus for channel gain mismatch of an ADC according to an embodiment of the present disclosure;

FIG. 4 is a structural block diagram of a calibration apparatus for channel gain mismatch of an ADC according to another embodiment of the present disclosure;

FIG. 5 is a structural block diagram of a calibration apparatus for channel gain mismatch of an ADC according to still another embodiment of the present disclosure;

FIG. 6 is a block diagram of a calibration circuit for channel gain mismatch of an ADC according to some embodiments of the present disclosure;

FIG. 7 is a principle block diagram of a calibration circuit for multi-channel ADC gain mismatch according to some embodiments of the present disclosure;

FIG. 8 is a complete flowchart of a calibration method for channel gain mismatch according to some embodiments of the present disclosure; and

FIG. 9 is a functional block diagram of a channel gain mismatch calibration module according to some embodiments of the present disclosure.

### DETAILED DESCRIPTION OF THE EMBODIMENTS

The embodiments of the present disclosure will be described below in detail with reference to the drawings and embodiments.

It should be noted that the terms “first” and “second” in the description, claims, and accompanying drawings of the present disclosure are used to distinguish similar objects, and are not necessarily used to describe a specific sequence or order.

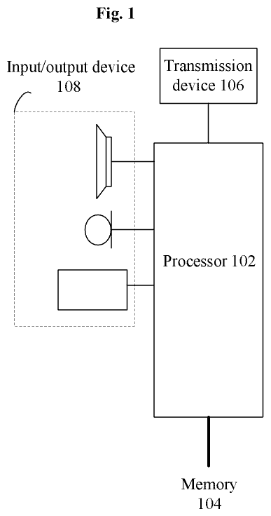

The method embodiments provided in the embodiments of the present disclosure may be implemented in a mobile terminal, a computer terminal, or a similar computing apparatus. Taking running on a computer terminal as an example, FIG. 1 is a hardware structure block diagram of a computer terminal for implementing a calibration method for channel gain mismatch of an ADC according to some embodiments of the present disclosure. As shown in FIG. 1, the computer terminal may include one or more (only one is shown in FIG. 1) processors 102 (each of the one or more processors 102 may include, but is not limited to, a processing apparatus such as a micro processing unit (e.g., Micro Processing Unit (MCU)) or a programmable logic device (e.g., Field Programmable Gate Array (FPGA)) and a memory 104 for storing data. The computer terminal may further include a transmission device 106 for a communication function and an input/output device 108. Those having ordinary skill in the art may understand that the structure shown in FIG. 1 is merely exemplary, which does not limit the structure of the foregoing computer terminal. For example, the computer terminal may further include more or fewer components than shown in FIG. 1, or have a different configuration from that shown in FIG. 1.

The memory 104 may be configured to store a computer program, for example, a software program and modules of application software, such as a computer program corresponding to the calibration method for the channel gain mismatch of the ADC in the embodiments of the present disclosure. The one or more processors 102 run the computer program stored in the memory 104, so as to execute various function applications and data processing, that is, to implement the foregoing method. The memory 104 may include a high-speed random access memory, and may also include a non-volatile memory, such as one or more magnetic storage devices, flash memory, or other non-volatile solid-state memory. In some examples, the memory 104 may further include a memory remotely located with respect to the one or more processors 102, and the memory remotely located with respect to the one or more processors 102 may be connected to the computer terminal via a network. Examples of such networks include, but are not limited to, the Internet, intranets, local area networks, mobile communication networks, and combinations thereof.

The transmission device 106 is configured to receive or transmit data via a network. Specific examples of the described network may include a wireless network provided by a communication provider of the computer terminal. In an example, the transmission device 106 may include a Network Interface Controller (NIC) that may be coupled to other network devices via a base station to communicate with the Internet. In an example, the transmission device 106 may be a Radio Frequency (RF) module for communicating wirelessly with the Internet.

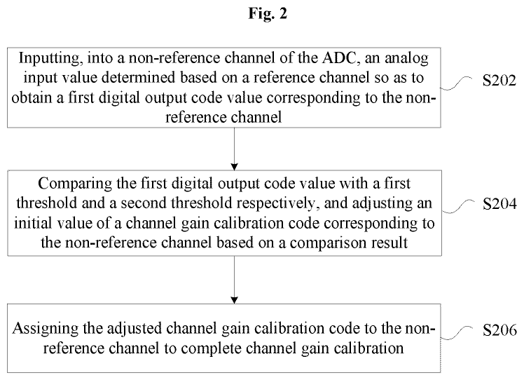

Provided in the present embodiment is a calibration method for channel gain mismatch of an ADC, which runs on the described computer terminal. FIG. 2 is a flowchart of a calibration method for channel gain mismatch of an ADC according to some embodiments of the present disclosure. As shown in FIG. 2, the flow includes the following operations S202 to S206.

In operation S202, an analog input value determined based on a reference channel is input into a non-reference channel of the ADC, so as to obtain a first digital output code value corresponding to the non-reference channel.

In operation S204, the first digital output code value is compared with a first threshold and a second threshold respectively, and an initial value of a channel gain calibration code corresponding to the non-reference channel is adjusted based on a comparison result.

In operation S206, the adjusted channel gain calibration code is assigned to the non-reference channel to complete channel gain calibration.

Before operation S202 of the embodiments of the present disclosure, the calibration method further includes: changing a differential analog voltage signal input into the reference channel of the ADC, and obtaining a second digital output code value corresponding to the reference channel; and determining the differential analog voltage signal corresponding to the second digital output code value as the analog input value when the second digital output code value jumps from the first threshold to the second threshold.

In the embodiments of the present disclosure, before the operation of changing the differential analog voltage signal input into the reference channel of the ADC, the calibration method further includes: setting an initial value of a positive end input voltage of the reference channel and an initial value of a negative end input voltage of the reference channel, wherein the initial value of the positive end input voltage is the same as the initial value of the negative end input voltage; and synchronously increasing a value of the positive end input voltage and decreasing a value of the negative end input voltage based on the initial value, so as to obtain the differential analog voltage signal to be input into the reference channel of the ADC.

In the embodiments of the present disclosure, at the beginning of calibration, relevant calculation parameters are configured, so that the working speed of the calibration circuit can be accelerated. In this way, an output value of an ADC unit of each channel can reach the vicinity of a final value as soon as possible. Then, the relevant calculation parameters are reset. By adopting the solution provided in the embodiments of the present disclosure, the working speed of the calibration circuit can be reduced, the precision of the calibration circuit can be increased at the same time, and the final calibration result is more precise.

In an exemplary embodiment, the initial value of the channel gain calibration code corresponding to the non-reference channel is equal to the channel gain calibration code corresponding to the reference channel.

The operation S204 of the embodiments of the present disclosure includes one of the following operations:
in a case where the first digital output code value is less than or equal to the first threshold, increasing the channel gain calibration code according to a preset step until the first digital output code value obtained based on the channel gain calibration code jumps from the first threshold to the second threshold, and recording the channel gain calibration code at a current moment as the adjusted channel gain calibration code corresponding to the non-reference channel; or
in a case where the first digital output code value is greater than or equal to the second threshold, decreasing the channel gain calibration code according to a preset step until the first digital output code value obtained based on the channel gain calibration code jumps from the second threshold to the first threshold, and recording the channel gain calibration code at a current moment as the adjusted channel gain calibration code corresponding to the non-reference channel.

It can be seen from the described operations that most of the calibration functions in the embodiments of the present disclosure are implemented in a digital domain, and therefore the calibration precision achieved during calibration will not be affected by the actual deviation of the analog circuit. That is, in a case that the nominal calibration precision is the same, the digital calibration method used in the embodiments of the present disclosure may achieve a higher practical calibration precision.

In an exemplary embodiment, there are multiple non-reference channels.

By means of the described operations, the adjustment of a channel gain calibration code is performed based on a comparison result between a digital output code value and a preset threshold value, i.e., the calibration of the channel gain mismatch of the ADC is performed in the digital domain. Compared with a multi-channel gain calibration method which relies on an analog circuit, the calibration according to the embodiments of the present disclosure can achieve a higher calibration precision. Therefore, the problem in the related art that a calibration method for multi-channel gain that relies on an analog circuit has relatively low calibration precision can be solved, thereby achieving the effect of improving the precision of channel gain calibration.

Through the description of the foregoing embodiments, those having ordinary skill in the art may clearly understand that the calibration method according to the foregoing embodiments may be implemented by software in addition to a necessary universal hardware platform, and definitely may also be implemented by hardware. However, in many cases, the former is a preferred implementation. Based on such understanding, the essence of the technical solutions of the embodiments of the present disclosure or the part contributing to the related art may be embodied in the form of a software product. The computer software product is stored in a storage medium (such as a Read-Only Memory (ROM)/Random Access Memory (RAM), a magnetic disk, and an optical disk) and includes several instructions for instructing a terminal device (which may be a mobile phone or a computer) to execute the calibration method described in the embodiments of the present disclosure.

A calibration apparatus for channel gain mismatch of an ADC is also provided in the embodiments of the present disclosure. The calibration apparatus is used for implementing the described embodiments and exemplary implementations, and what has been described will not be elaborated. The term “module”, as used hereinafter, is a combination of software and/or hardware capable of realizing a predetermined function. Although the calibration apparatus described in the following embodiments is preferably implemented by software, implementation of hardware or a combination of software and hardware is also possible and conceived.

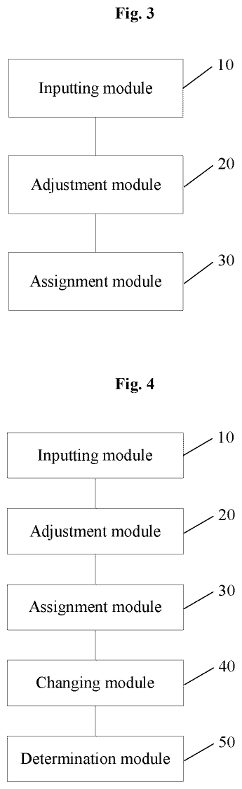

FIG. 3 is a structural block diagram of a calibration apparatus for channel gain mismatch of an ADC according to an embodiment of the present disclosure. As shown in FIG. 3, the calibration apparatus includes: an inputting module 10, an adjustment module 20 and an assignment module 30.

The inputting module 10 is configured to input, into a non-reference channel of the ADC, an analog input value determined based on a reference channel so as to obtain a first digital output code value corresponding to the non-reference channel.

The adjustment module 20 is configured to compare the first digital output code value with a first threshold and a second threshold respectively, and adjust an initial value of a channel gain calibration code corresponding to the non-reference channel based on a comparison result.

The assignment module 30 is configured to assign the adjusted channel gain calibration code to the non-reference channel to complete channel gain calibration.

FIG. 4 is a structural block diagram of a calibration apparatus for channel gain mismatch of an ADC according to another embodiment of the present disclosure. As shown in FIG. 4, besides all the modules shown in FIG. 3, the calibration apparatus further includes:
a changing module 40, configured to change a differential analog voltage signal input into the reference channel of the ADC, and obtain a second digital output code value of the ADC unit corresponding to the reference channel output in response to the differential analog voltage signal; and
a determination module 50, configured to determine the differential analog voltage signal corresponding to the second digital output code value as the analog input value when the second digital output code value jumps from the first threshold to the second threshold.

FIG. 5 is a structural block diagram of a calibration apparatus for channel gain mismatch of an ADC according to still another embodiment of the present disclosure. As shown in FIG. 5, in addition to all the modules shown in FIG. 4, the calibration apparatus further includes:
a setting module 60, configured to set an initial value of a positive end input voltage of the reference channel and an initial value of a negative end input voltage of the reference channel, wherein the initial value of the positive end input voltage is the same as the initial value of the negative end input voltage; and
an adding module 70 configured to synchronously increase a value of the positive end input voltage and decrease a value of the negative end input voltage based on the initial value, so as to obtain the differential analog voltage signal to be input into the reference channel of the ADC.

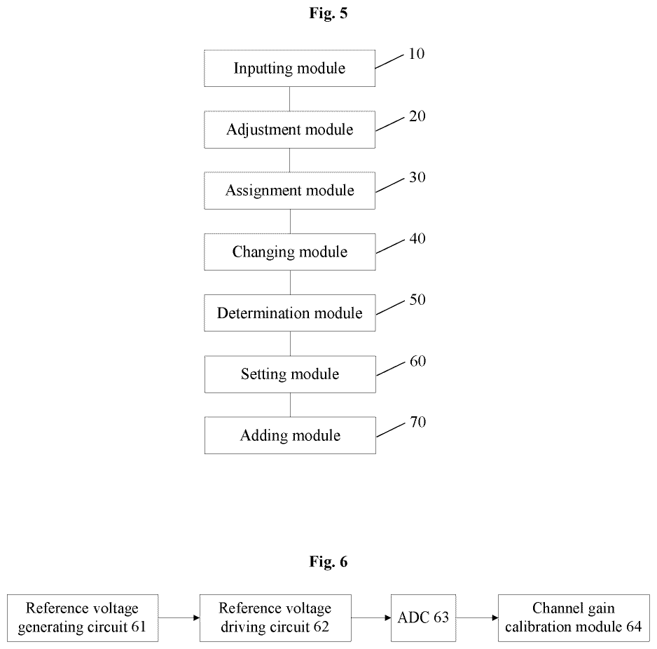

FIG. 6 is a block diagram of a calibration circuit for channel gain mismatch of an ADC according to some embodiments of the present disclosure. The calibration circuit is applied to the described calibration method for the channel gain mismatch of the ADC. As shown in FIG. 6, the calibration circuit includes:
a reference voltage generating circuit 61, a reference voltage driving circuit 62, an ADC 63, and a channel gain calibration module 64.

The reference voltage generating circuit 61 is configured to provide a reference voltage according to a parameter requirement of the calibration circuit for the channel gain mismatch of the ADC, and send the reference voltage to the reference voltage driving circuit.

The reference voltage driving circuit 62 is configured to provide a reference voltage for an ADC unit of each channel in M channels, wherein the M channels include one reference channel and M-1 non-reference channels, and M is an integer greater than 1.

The ADC 63 includes N-bit ADC units corresponding to the M channels, and each of the N-but ADC units is configured to convert an input differential analog voltage signal of the reference voltage into a digital output signal and output the digital output signal, wherein N is an integer greater than zero.

The channel gain calibration module 64 is configured to calculate and adjust a gain coefficient for a digital output code value output by the ADC unit of each channel, and determine a gain calibration code corresponding to each channel.

In the embodiments of the present disclosure, the configuration of the calculation parameters is completed in the digital circuit, and thus is not influenced by the actual situation of the analog circuit, so that the modifiability and configurability are higher.

It should be noted that each module may be implemented by software or hardware. The latter may be implemented in the following manner, but is not limited thereto. All the modules are located in a same processor; alternatively, the modules are located in different processors in an arbitrary combination.

To facilitate understanding of the technical solutions provided in the present disclosure, the technical solution is described as follows in detail with reference to the embodiments under specific scenarios.

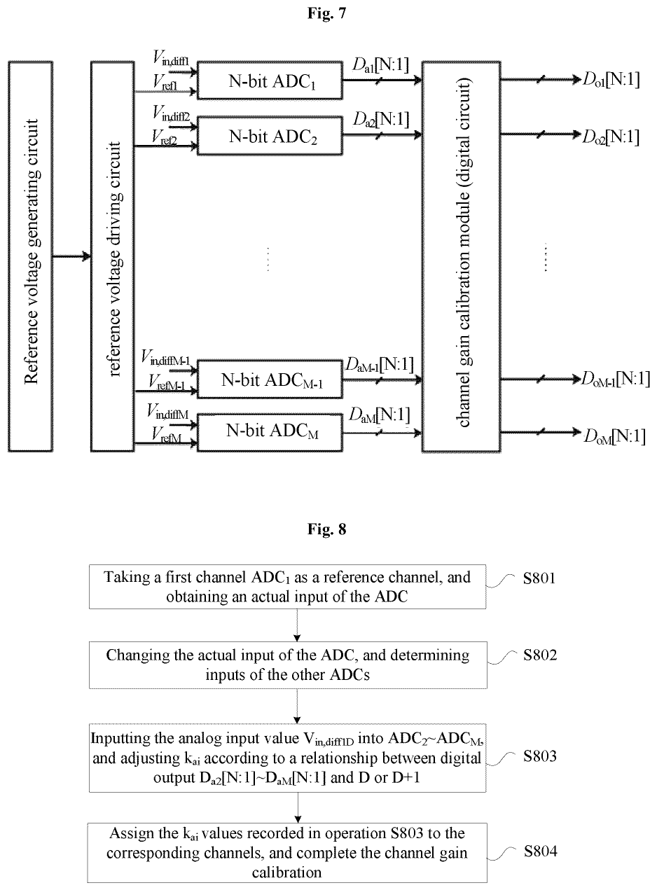

Provided is a calibration method for channel gain mismatch in a time-interleaved ADC or a multi-channel ADC. FIG. 7 is a principle block diagram of a calibration circuit for multi-channel ADC gain mismatch according to some embodiments of the present disclosure. As shown in FIG. 7, the entire calibration apparatus for gain mismatch includes the following modules:
a reference voltage generating circuit, which is configured to provide a suitable reference voltage according to a parameter requirement of the calibration circuit for the channel gain mismatch of the ADC, and send the reference voltage to the reference voltage driving circuit;
a reference voltage driving circuit, which is configured to increase a driving capability of a reference voltage, and provide reference voltages for ADC units of respective channels in M channels, wherein these reference voltages are respectively denoted as V_{ref1}, V_{ref2}, . . . . V_{refM-1} and V_{refM};
N-bit ADC units corresponding to the M channels, wherein inputs of these ADC units are differential analog voltage signals V_{in,diff1}, V_{in,diff2}, . . . . V_{in,diffM-1} and V_{in,diffM} respectively, reference voltages of these ADC units are respectively V_{ref1}, V_{ref2}, . . . . V_{refM-1} and V_{refM}, and corresponding digital output signals of these ADC units are respectively Dₐ₁[N:1], Dₐ₂[N:1], . . . . D_{aM-1}[N:1] and D_{aM}[N:1];
a channel gain calibration module, which is a pure digital circuit, and since there are M ADC units corresponding to the M channels in an analog circuit, there are M calculation units in the channel gain calibration module, which are configured to calculate and adjust a gain coefficient for an output codeword output by the ADC unit of the respective channels, then perform comparison on the calculation result of each channel to obtain corresponding gain calibration codes kₐ₁, kₐ₂, . . . k_{aM-1} and k_{aM}, multiply the foregoing channel digital codewords Dₐ₁[N:1], Dₐ₂ [N:1], . . . . D_{aM-1} [N:1] and D_{aM} [N:1] by the corresponding gain calibration codes kₐ₁, kₐ₂, . . . k_{aM-1} and k_{aM} respectively, and obtain calibrated output codewords Dₒ₁[N:1], Dₒ₂[N:1], . . . . D_{OM-1}[N:1] and DOM [N:1] after performing truncation at a high bit on the multiplication result, so as to complete the relevant work of gain calibration.

FIG. 8 is a complete flowchart of a calibration method for channel gain mismatch according to some embodiments of the present disclosure. A differential ADC is taken as an example for description. That is, a positive end voltage Vᵢₙₚ and a negative end voltage Vᵢₙₙ of a differential analog signal are input into the differential ADC, digital quantization corresponding to Vᵢₙₚ-Vᵢₙₙ is output from the differential ADC, and an input common-mode voltage of the differential ADC is V_{CM}. As shown in FIG. 8, the flow includes the following operations S801 to S804.

In operation S801, a first channel ADC₁ is taken as a reference channel, and an actual input of the ADC is obtained.

Specifically, the following operations are performed on ADC₁. An initial value of Vᵢₙₚ and an initial value of Vᵢₙₙ are set as V_{CM}. Then, Vᵢₙₚ is increased and Vᵢₙₙ is decreased synchronously. It should be noted that the increase/decrease speed should not be too fast so as to avoid introducing a relatively large error, and an increase amount of Vᵢₙₚ and a decrease amount of Vᵢₙₙ need to be kept equal at any moment. In this case, Vᵢₙₚ and Vᵢₙₙ are respectively represented by formula (1) and formula (2):

$${V}_{inp} = {V}_{CM} + {V}_{in , diff 1} / 2 \qquad formula ( 1 )$$

$${V}_{inn} = {V}_{CM} - {V}_{in , diff 1} / 2 \qquad formula ( 2 )$$

As can be seen from formula (1) and formula (2), the actual input to the ADC is V_{in,diff1}. In this embodiment, the amplitude of the analog input signal may be increased in a linear increase manner or a nonlinear increase manner.

Although this embodiment is described by taking the addition of V_{in,diff} as an example, the calibration function can also be realized by actually decreasing by V_{in,diff}.

In operation S802, the actual input of the ADC is changed, and inputs of the other ADCs are determined;

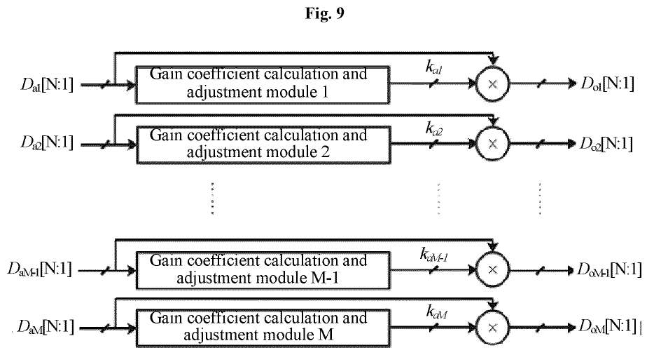

Specifically, as Vin, diff increases, the output code value of ADC₁ also changes continuously, and the digital output code value Dₐ₁ [N:1] is observed, when Dₐ₁ [N:1] jumps from a certain value D (D needs to be less than the maximum value of the ADC digital output) to D+1 (it is considered that Dₐ₁ [N:1] is exactly between D and D+1 at this time), the analog input value V_{in,diffID} at this time is recorded, and this analog input value V_{in,diffID} serves as input values input into other ADC channels. Because ADC₁ is in the reference channel, the channel gain calibration code ka1 is set to 1, and according to the correspondence in FIG. 9, the final digital output of the first channel is Dₒ₁ [N:1]=kₐ₁Dₐ₁[N:1]=Dₐ₁ [N:1].

In operation S803, the analog input value V_{in,diffID} is input into ADC₂~ADC_{M}, and kₐᵢ is adjusted according to a relationship between digital output Dₐ₂ [N:1] ~D_{aM} [N:1] and D or D+1.

Specifically, the analog input of the ADC₂~ADC_{M} is set as V_{in,diffID}, and the initial value of the channel gain calibration code kₐ₂~k_{aM} is 1. The digital output Dₐ₂ [N:1] ~D_{aM} [N:1] corresponding to each channel at this time is respectively compared with D or D+1. If Dₐᵢ[N:1] (i=2, 3, . . . . M)≤D, kₐᵢ is continuously increased (the adjustment step length of kₐᵢ needs to be set to be small enough, for example, lower than 0.05, otherwise the precision of calibration may be poor), until Dₐᵢ[N:1] turns from D to D+1, and the value of kₐᵢ at this time is recorded. Similarly, if Dₐᵢ[N:1](i=2, 3, . . . . M)≥D+1, kₐᵢ is continuously decreased until Dₐᵢ[N:1] turns from D+1 to D, and the value of kₐᵢ at this time is recorded.

In operation S804, the kₐᵢ values recorded in operation S803 are assigned to the corresponding channels, and the channel gain calibration is completed.

In the embodiments of the present disclosure, an ADC with a differential input structure is used for description, and in fact, the calibration method is also applicable to an ADC with a single-ended input structure.

Specifically, in this embodiment, the calibration principle for the channel gain mismatch is as follows.

For the same input signal, theoretically, the output digital code words of the channels should be completely consistent. However, because of the existence of the gain error of each channel, the following relationship holds (taking the first channel as a reference)

$${D}_{a i} [ N : 1 ] = q i {D}_{a 1} [ N : 1 ] \qquad formula ( 3 )$$

wherein qᵢ(i=2, . . . , M) is a gain error of each channel relative to the first channel respectively, and ideally there should be the following equation:

$${q}_{2} = {q}_{3} = {q}_{4} = … = {q}_{M} = 1 \qquad formula ( 4 )$$

However, due to the matching problem of the analog circuit, the relationships in formula (4) are difficult to meet, and therefore, these parameters need to be modified.

For the digital output of the ADC unit of channel i, according to formula (3), when qi<1, Dₐᵢ[N:1]<Dₐ₁ [N:1] (corresponding to the case where Dₐᵢ[N:1](i=2, 3, . . . , M)≤D in the calibration operation S803), so the gain calibration coefficient kₐᵢ should be increased; when qᵢ>1, Dₐᵢ[N:1]> [N:1] (corresponding to the case where Dₐᵢ[N:1] (i=2, 3, . . . , M)>D+1 in the calibration operation S803), so the gain calibration coefficient kₐᵢ needs to be reduced.

It can be seen from FIG. 9 and formula (3) that for all channels, the final digital output is

$${D}_{o i} [ N : 1 ] = {q}_{i} {k}_{ai} {D}_{a i} [ N : 1 ] \qquad formula ( 5 )$$

Since the first channel is the reference channel, q₁ and kₐ₁ can both be set directly to 1. With regard to other channels, after the calibration is completed, the output codewords are all controlled to fall in the scope between D and D+1, and at this time, the same input voltage corresponds to the same quantization range, i.e., the following relationship is established:

$${q}_{i} {k}_{a i} = 1 \qquad formula ( 6 )$$

That is to say, the channel gains of respective channels are equal, and the channel gain mismatch is eliminated.

The calibration method or circuit in the embodiments of the present disclosure is mainly applied in the field of high-speed electronic communications. A corresponding related product module includes a radio frequency (RF) receiver, a serializer/de-serializer, an ultra-high-speed time-interleaved ADC, and a multi-channel ADC array, among others. Here, the time-interleaved structure is a type of circuit configuration for multi-channel interleaved data output.

The application scenario of the embodiments of the present disclosure is the working stage of channel gain mismatch calibration before the time-interleaved ADC or multi-channel ADC array starts normal operation, which belongs to a front-end calibration scheme. Specifically, the solution provided in the embodiments of the present disclosure can be applied to a channel gain mismatch calibration stage of a multi-channel time-interleaved ADC; a gain error calibration of a high-precision single-channel ADC; and a mismatch calibration of various passive device arrays (resistor arrays, capacitor arrays, etc.).

The calibration method for the channel gain mismatch in the embodiments of the present disclosure is implemented by using a digital circuit. The precision that can be achieved by the calibration method is not affected by the deviation of the manufacturing process of an analog circuit. That is to say, in a case that the nominal calibration precision is the same, the digital calibration method used in the embodiments of the present disclosure has a higher practical calibration precision. In addition, the technical solution in the embodiments of the present disclosure has higher modifiability and configurability. Due to the implementation of gain calibration functions using nearly pure digital circuits, the system has better modifiability and configurability when the calibration circuit is actually working. For example, at the beginning of calibration, relevant calculation parameters are configured to speed up the operation of the calibration circuit, so that the output values of respective channel ADCs can quickly approach their final values. Then, the relevant calculation parameters are reset to reduce the working speed of the calibration circuit while increasing its precision, allowing the final calibration results to be more precise. The aforementioned configuration of these calculation parameters is completed within the digital circuit, thus being unaffected by the actual conditions of analog circuits, which leads to higher modifiability and configurability. In theory, as long as there are sufficient resources in the digital circuit, the calibration precision can be infinitely refined.

The embodiments of the present disclosure further provide a computer readable storage medium. The computer readable storage medium stores a computer program, wherein the computer program is configured to execute the operations in any one of the method embodiments during running.

In an exemplary embodiment, the computer readable storage medium may include, but is not limited to, any medium that can store a computer program, such as a Universal Serial Bus (USB) flash drive, a Read-Only Memory (ROM), a Random Access Memory (RAM), a removable hard disk, a magnetic disk, or an optical disc.

The embodiments of the present disclosure further provide an electronic device, including a memory and a processor, wherein the memory stores a computer program, and the processor is configured to run the computer program so as to execute the operations in any one of the method embodiments.

In an exemplary embodiment, the electronic device may further include a transmission device and an input/output device, wherein the transmission device is connected to the processor, and the input/output device is connected to the processor.

For specific examples in this embodiment, reference may be made to the examples described in the foregoing embodiments and exemplary embodiments, and details are not repeatedly described in this embodiment.

Obviously, those having ordinary skill in the art should understand that each module or each operation of the described embodiments of the present disclosure can be implemented by a universal computing device, they may be centralized on a single computing device or distributed on a network composed of a plurality of computing devices, they can be implemented by program codes executable by a computing apparatus, and thus can be stored in a storage apparatus and executed by the computing apparatus. Furthermore, in some cases, the shown or described operations may be executed in an order different from that described here, or they are made into integrated circuit modules respectively, or a plurality of modules or operations therein are made into a single integrated circuit module for implementation. Thus, the present disclosure is not limited to any particular combination of hardware and software.

The foregoing descriptions are merely exemplary embodiments of the present disclosure, but are not intended to limit the present disclosure. For those having ordinary skill in the art, the present disclosure may have various modifications and variations. Any modifications, equivalent replacements, improvements and the like made within the principle of the present disclosure shall fall within the scope of protection of the present disclosure.

1. A calibration method for channel gain mismatch of an Analog-to-Digital Converter (ADC), comprising:
inputting, into a non-reference channel of the ADC, an analog input value determined based on a reference channel so as to obtain a first digital output code value corresponding to the non-reference channel;
comparing the first digital output code value with a first threshold and a second threshold respectively, and adjusting a channel gain calibration code corresponding to the non-reference channel based on a comparison result; and
assigning the adjusted channel gain calibration code to the non-reference channel to complete channel gain calibration.

2. The calibration method according to claim 1, wherein before inputting, into the non-reference channel, the analog input value determined based on the reference channel, the calibration method further comprises:
changing a differential analog voltage signal input into the reference channel of the ADC, and obtaining a second digital output code value corresponding to the reference channel; and
determining the differential analog voltage signal corresponding to the second digital output code value as the analog input value when the second digital output code value jumps from the first threshold to the second threshold.

3. The calibration method according to claim 12, wherein before changing the differential analog voltage signal input into the reference channel of the ADC, the calibration method further comprises:
setting an initial value of a positive end input voltage of the reference channel and an initial value of a negative end input voltage of the reference channel, wherein the initial value of the positive end input voltage is the same as the initial value of the negative end input voltage; and
synchronously increasing a value of the positive end input voltage and decreasing a value of the negative end input voltage based on the initial value, so as to obtain the differential analog voltage signal to be input into the reference channel of the ADC.

4. The calibration method according to claim 1, wherein an initial value of the channel gain calibration code corresponding to the non-reference channel is equal to the channel gain calibration code corresponding to the reference channel.

5. The calibration method according to claim 1, wherein adjusting the channel gain calibration code corresponding to the non-reference channel based on the comparison result comprises one of:
in a case where the first digital output code value is less than or equal to the first threshold, increasing the channel gain calibration code according to a preset step until the first digital output code value obtained based on the channel gain calibration code jumps from the first threshold to the second threshold, and recording the channel gain calibration code at a current moment as the adjusted channel gain calibration code corresponding to the non-reference channel; or
in a case where the first digital output code value is greater than or equal to the second threshold, decreasing the channel gain calibration code according to a preset step until the first digital output code value obtained based on the channel gain calibration code jumps from the second threshold to the first threshold, and recording the channel gain calibration code at a current moment as the adjusted channel gain calibration code corresponding to the non-reference channel.

6. The calibration method according to claim 1, wherein there are multiple non-reference channels.

7. (canceled)

8. (canceled)

9. (canceled)

10. A calibration circuit for channel gain mismatch of an Analog-to-Digital Converter (ADC), applied in the calibration method according to claim 1, wherein the calibration circuit comprises: a reference voltage generating circuit, a reference voltage driving circuit, the ADC, and a channel gain calibration module, wherein
the reference voltage generating circuit is configured to provide a reference voltage according to a parameter requirement of the calibration circuit for the channel gain mismatch of the ADC, and send the reference voltage to the reference voltage driving circuit;
the reference voltage driving circuit is configured to provide a reference voltage for an ADC unit of each channel in M channels, wherein the M channels comprise one reference channel and M-1 non-reference channels, and M is an integer greater than 1;
the ADC comprises N-bit ADC units corresponding to the M channels, and each of the N-but ADC units is configured to convert an input differential analog voltage signal of the reference voltage into a digital output signal and output the digital output signal, wherein N is an integer greater than zero; and
the channel gain calibration module is configured to calculate and adjust a gain coefficient for a digital output code value output by the ADC unit of each channel, and determine a gain calibration code corresponding to each channel.

11. A computer readable storage medium, wherein the computer readable storage medium stores a computer program, and the computer program, when executed by a processor for calibration for channel gain mismatch of an Analog-to-Digital Converter (ADC), causes the processor to implement operations comprising:
inputting, into a non-reference channel of the ADC, an analog input value determined based on a reference channel so as to obtain a first digital output code value corresponding to the non-reference channel;
comparing the first digital output code value with a first threshold and a second threshold respectively, and adjusting a channel gain calibration code corresponding to the non-reference channel based on a comparison result; and
assigning the adjusted channel gain calibration code to the non-reference channel to complete channel gain calibration.

12. An electronic device, comprising: a memory, a processor, and a computer program stored in the memory and capable of running on the processor, wherein the processor, when executing the computer program, implements operations of the calibration method according to claim 1.

13. The calibration method according to claim 3, wherein in a case where the ADC is a differential ADC, the initial value of the positive end input voltage and the initial value of the negative end input voltage are set as V_{CM}, wherein V_{CM} is an input common-mode voltage of the differential ADC.

14. The calibration method according to claim 1, wherein the ADC is a differential ADC or a single-ended ADC.

15. The calibration circuit according to claim 10, wherein the channel gain calibration module is a digital circuit.

16. The calibration circuit according to claim 15, wherein in correspondence to the M ADC units corresponding to the M channels in an analog circuit, there are M calculation units in the channel gain calibration module

17. The computer readable storage medium according to claim 11, wherein the computer program, when executed by the processor, causes the processor to implement the following operations before inputting, into the non-reference channel, the analog input value determined based on the reference channel:
changing a differential analog voltage signal input into the reference channel of the ADC, and obtaining a second digital output code value corresponding to the reference channel; and
determining the differential analog voltage signal corresponding to the second digital output code value as the analog input value when the second digital output code value jumps from the first threshold to the second threshold.

18. The computer readable storage medium according to claim 17, wherein the computer program, when executed by the processor, causes the processor to implement the following operations before changing the differential analog voltage signal input into the reference channel of the ADC:
setting an initial value of a positive end input voltage of the reference channel and an initial value of a negative end input voltage of the reference channel, wherein the initial value of the positive end input voltage is the same as the initial value of the negative end input voltage; and
synchronously increasing a value of the positive end input voltage and decreasing a value of the negative end input voltage based on the initial value, so as to obtain the differential analog voltage signal to be input into the reference channel of the ADC.

19. The computer readable storage medium according to claim 11, wherein an initial value of the channel gain calibration code corresponding to the non-reference channel is equal to the channel gain calibration code corresponding to the reference channel.

20. The computer readable storage medium according to claim 11, wherein adjusting the channel gain calibration code corresponding to the non-reference channel based on the comparison result comprises one of:
in a case where the first digital output code value is less than or equal to the first threshold, increasing the channel gain calibration code according to a preset step until the first digital output code value obtained based on the channel gain calibration code jumps from the first threshold to the second threshold, and recording the channel gain calibration code at a current moment as the adjusted channel gain calibration code corresponding to the non-reference channel; or
in a case where the first digital output code value is greater than or equal to the second threshold, decreasing the channel gain calibration code according to a preset step until the first digital output code value obtained based on the channel gain calibration code jumps from the second threshold to the first threshold, and recording the channel gain calibration code at a current moment as the adjusted channel gain calibration code corresponding to the non-reference channel.

21. The computer readable storage medium according to claim 11, wherein there are multiple non-reference channels.

22. The computer readable storage medium according to claim 18, wherein in a case where the ADC is a differential ADC, the initial value of the positive end input voltage and the initial value of the negative end input voltage are set as V_{CM}, wherein V_{CM} is an input common-mode voltage of the differential ADC.

23. The computer readable storage medium according to claim 11, wherein the ADC is a differential ADC or a single-ended ADC.
